(19) United States
(12) Patent Application Publication
(10) Pub. No.: US 2010/0002373 A1
(43) Pub. Date: Jan. 7, 2010

(54) HEAT DISSIPATING DEVICE FOR ELECTRONIC DEVICE

(75) Inventors: LEI GUO, Shenzhen City (CN); YU-HSU LIN, San Jose, CA (US); JENG-DA WU, Tu-Cheng (TW); YANG LI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO. LTD., ShenZhen City (CN); HON HAI PRECISION INDUSTRY CO., LTD., Tu-Cheng (TW)

(21) Appl. No.: 12/425,609

(22) Filed: Apr. 17, 2009

(30) Foreign Application Priority Data
Jul. 3, 2008 (CN) 200820301429.4

(51) Int. Cl. H05K 7/20; G06F 1/20; F28F 13/00

(52) U.S. Cl. 361/679.47; 361/679.54; 165/80.3

(57) ABSTRACT

A heat dissipating device is provided. The heat dissipating device includes a seat and a plurality of fins secured on the seat. The fins are regularly aligned in a matrix. A first set of fins comprise of a convex profile.

### BACKGROUND

1. Technical Field

The present disclosure relates to heat dissipating devices, and particularly, to a heat dissipating device for an electronic device.

2. Description of Related Art

Electronic devices generate heat during operation. Electronic components may overheat and be damaged if this heat is not removed. Some electronic devices use a fan and a heatsink to draw heat away from the electronic components. Generally, the heatsink includes a base adhered to a component (such as CPU or other chips) generating heat, and a plurality of fins perpendicularly mounted on the base. The fins define a plurality of air paths configured for allowing air to flow therebetween. However, the side configuration of each of the conventional fins of the heatsink is generally rectangular shape. When the air from the fan is flowed into the air path of the fins, part of the air is blocked by the side of the fins. This will decrease the efficiency of the heat removal.

Accordingly, what is needed is a heat dissipating device with improved fin configurations to increase heat dissipating efficiency.

### BRIEF DESCRIPTION OF THE DRAWINGS

FIG. 1 is an isometric view of one embodiment of a heat dissipating device mounted in an electronic device.

FIG. 2 is an isometric view similar to FIG. 1, viewed from another aspect.

FIG. 3 is an isometric view of the heat dissipating device of FIG. 1.

FIG. 4 is a top, partial view of the heat dissipating device of FIG. 3.

FIG. 5 is a top, partial view of an alternative embodiment of the heat dissipating device.

### DETAILED DESCRIPTION

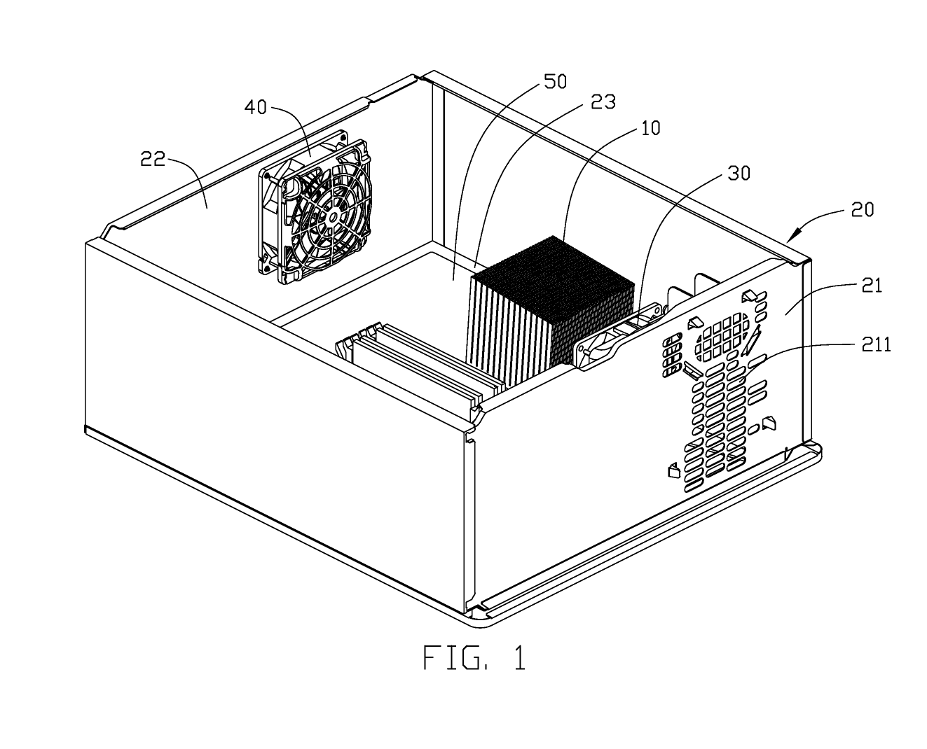

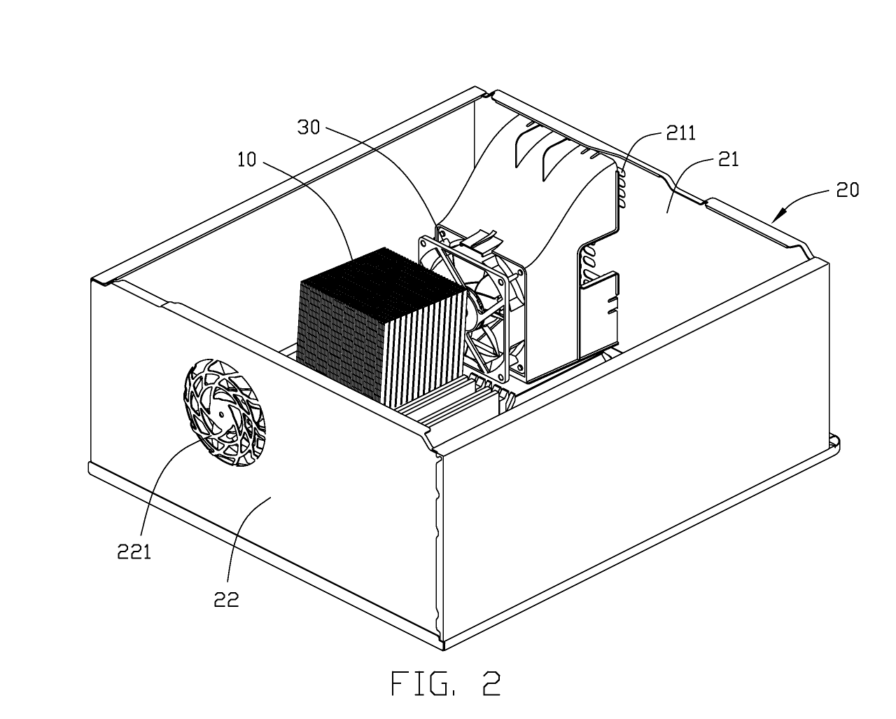

Referring to FIGS. 1 and 2, one embodiment of a heat dissipating device 10 is mounted in an electronic device enclosure, such as a computer enclosure 20, to remove heat generated by the components in the electronic device.

The computer enclosure 20 includes a front wall 21 and a rear wall 22 opposite to the front wall 21. The front wall 21 defines an air inlet 211 and the rear wall 22 defines an air outlet 221. A first fan module 30 is attached to the front wall 21 corresponding to the air inlet 211. A second fan module 40 is attached to the rear wall 22 corresponding to the air outlet 221. The heat dissipating device 10 is attached above an electronic component (for example, a chip) on a motherboard 50, adjacent to the first fan module 30, to remove heat generated by the component from the computer enclosure 20. The second fan module 40 is aligned with the heat dissipating device 10 and the first fan module 30.

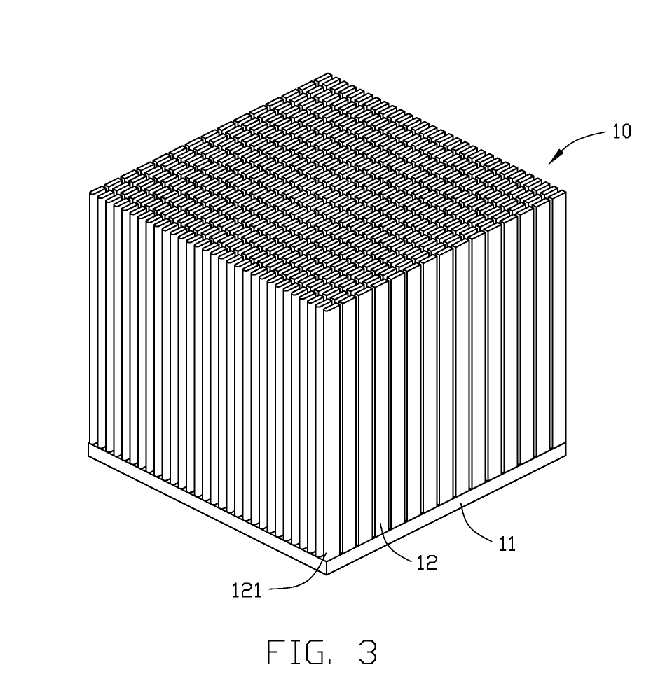

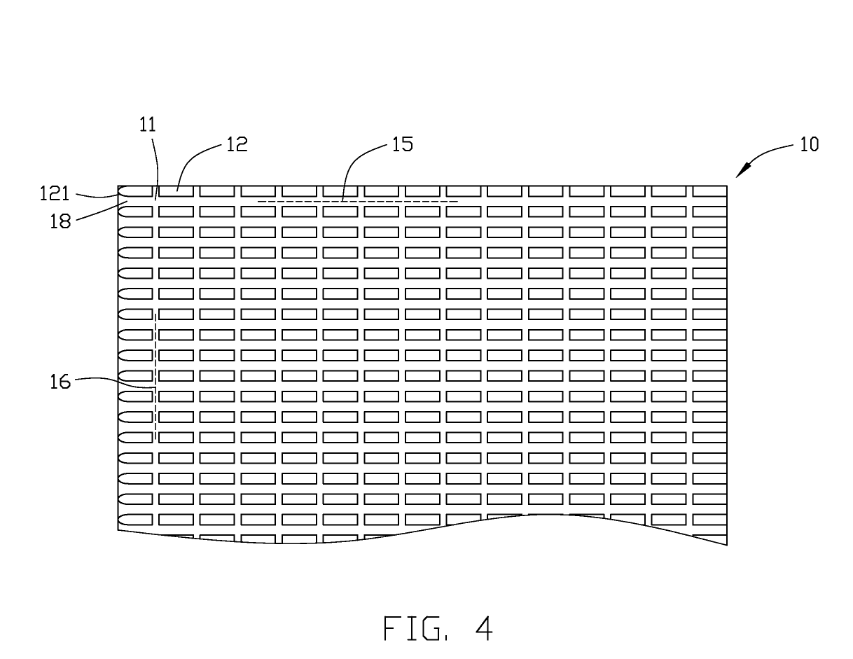

Referring also to FIGS. 2 and 3, the heat dissipating device 10 includes a seat 11 secured on the motherboard 50. A plurality of substantially rectangular-shaped fins 12 perpendicularly extends away from the seat 11. The fins 12 are regularly aligned in a matrix manner, thereby defining rows of fins 12, and columns of fins 12. The columns of the fins 12 are parallel to a side of the seat 11. The fins 12 cooperatively define a plurality of first air paths 15 parallel to the side of the seat 11 and a plurality of second air paths 16 perpendicular to the first air paths 15. An outermost column of fins 12 are configured to have a convex profile facing the first fan module 30. See FIGS. 4-6, a top view (or cut view) of each fin 12 in the outermost column is substantially rectangular shape with one side facing the first fan module 30 replaced by a curved line 121. Top views (or cut views) of other fins 12 except that of the outermost column are rectangular shape.

Referring to FIG. 4, one embodiment of the curved line 121 is semicircular shape. A guiding groove 18 wider than the majority of the rest of each first air path 15 is defined between the outside curved portions of every two adjacent fins 12 to allow air from the first fan module 30 to flow more efficiently into the guiding paths 15.

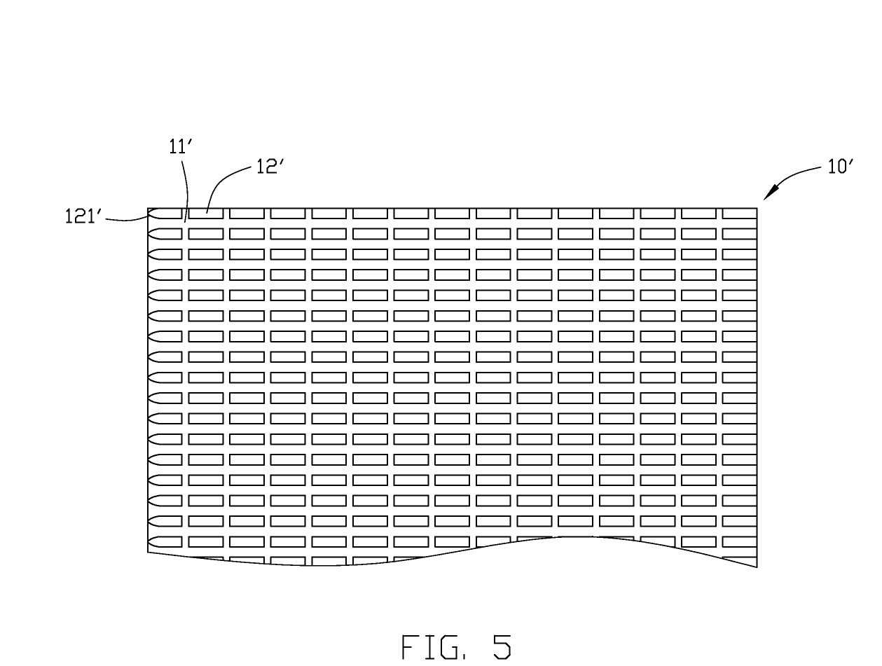

Referring to FIG. 5, another embodiment of the curved line 121′ is parabola shape. In other embodiments, the curved line may be configured oval shape or other shapes configured for airflow from the first fan module 10 flowing more efficiently into the fins 12 to remove heat.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A heat dissipating device, comprising:
a seat; and
a plurality of fins secured on the seat, the fins being regularly aligned in a matrix, a first set of fins comprise of a convex profile.

2. The heat dissipating device of claim 1, wherein the fins define a plurality of rows and columns, and the fins define a plurality of first air paths parallel to one side of the seat and a plurality of second air paths perpendicular to the first air paths.

3. The heat dissipating device of claim 1, wherein a second set of fins of are substantially rectangular in shape.

4. The heat dissipating device of claim 1, wherein the convex profile is semicircular shape.

5. The heat dissipating device of claim 1, wherein the convex profile is oval shape.

6. The heat dissipating device of claim 1, wherein the convex profile is parabola shape.

7. A heat dissipating assembly, comprising:
an electronic device enclosure having a motherboard secured in the enclosure;
a heat dissipating device mounted on the motherboard, the heat dissipating device comprising:
a seat; and
a plurality of fins secured on the seat, the fins being regularly aligned in a matrix, a first set of fins comprise of a convex profile;
the plurality of fins define a plurality of first air paths parallel to each other; and
a fan module mounted in the electronic device enclosure, wherein the first set of fins are the closest to the fan module.

8. The heat dissipating assembly of claim 7, wherein the fins define a plurality of columns and rows, and the fins define a plurality of second air paths perpendicular to the first air paths.

9. The heat dissipating assembly of claim 7, wherein a second set of fins are substantially rectangular in shape.

10. The heat dissipating assembly of claim 7, wherein the convex profile is semicircular shape.

11. The heat dissipating assembly of claim 7, wherein the convex profile is oval shape.

12. The heat dissipating assembly of claim 7, wherein the convex profile is parabola shape.

13. A heat dissipating device, comprising:
a seat attachable to a motherboard of a computer; and
a plurality of fins perpendicularly secured on the seat, the fins being regularly aligned in a matrix, the fins determining a plurality of first air paths parallel to each other, one end of each first air path being wider than the majority of the rest of the air path.

14. The heat dissipating device of claim 13, wherein the fins are regularly aligned in a plurality of columns and rows, the plurality of columns of fins define a plurality of second air paths perpendicular to the first air paths.
